(19) United States
(12) Patent Application Publication
(10) Pub. No.: US 2025/0087280 A1
(43) Pub. Date: Mar. 13, 2025

(54) METHOD AND SYSTEM FOR REFRESHING FLASH MEMORY DEVICE

(71) Applicant: INNODISK CORPORATION, New Taipei City (TW)

(72) Inventors: Ting-Chiang Liu, New Taipei City (TW); Chung-Yi Lai, New Taipei City (TW)

(73) Assignee: INNODISK CORPORATION, New Taipei City (TW)

(21) Appl. No.: 18/517,629

(22) Filed: Nov. 22, 2023

(30) Foreign Application Priority Data
Sep. 8, 2023 (TW) 112134400

(51) Int. Cl. G11C 16/34

(52) U.S. Cl. CPC G11C 16/3431

(57) ABSTRACT

A method and a system for refreshing a flash memory device are provided. The system mainly includes a host, and a main control unit and a plurality of flash memory units arranged in the flash memory device. The method includes the following steps: providing a performance value of the plurality of flash memory units from the main control unit to the host; providing a refresh command from the host to the main control unit when the performance value is lower than a pre-determined value; and controling the plurality of flash memory units, by the the main control unit, to stop current operations, and executing a refresh operation on the plurality of flash memory units.

### CROSS-REFERENCE TO RELATED APPLICATION AND CLAIM OF PRIORITY

The application claims the benefit of Taiwan Patent Application No. 112134400, filed on Sep. 8, 2023, at the Taiwan Intellectual Property Office, the disclosures of which are incorporated herein in their entirety by reference.

### FIELD OF THE INVENTION

The present invention generally relates to a method and a system for refreshing a flash memory device and, more particularly, to a method and a system for refreshing a flash memory device that can enhance the performance of the flash memory device.

### BACKGROUND OF THE INVENTION

Flash memories consume power when writing or reading data. Once the data is written, even if the power is turned off, the stored data can still be retained for a period of time. In addition, the flash memories have many advantages, such as small size, large capacity, fast reading and writing speed, quietness and power saving, shock resistance and moisture resistance and so on, so they are widely used in embedded systems, portable information products and consumer electronics.

However, although the flash memories have many advantages in addition to convenience, there are still some limitations and defects, such as read disturb, write disturb, data retention, wear-out and so on.

CN105843550B discloses a technology for reducing read disturb errors. TWI756297B discloses a technology that is capable of performing a read retry operation when a read error occurs in any one of the storage regions. CN109949850A discloses a technology that uses a retry table, which is provided to store voltage values corresponding to various predefined error types. When a data access error occurs, each voltage value in the retry table is tested in sequence until the voltage value corresponding to the current error type is tested. Based on the error type with respect to the voltage value, the corresponding access adjusting action is carried out. TW201818414A discloses that the temperature is detected using a temperature sensor, and the data retention period is calculated according to the temperature and the number of erase cycles. In the data retention period, the data in each memory block is erased and rewritten. By refreshing each memory block in the data retention period, the data retention period is refreshed to extend the data retention period of the flash memory and prevent the data from being lost due to errors resulting from exceeding of the data retention period, read disturb or wear-out.

However, the above technologies still cannot comprehensively and immediately overcome the limitations and defects of a flash memory. For example, a flash memory may still suffer from errors resulting from the data retention problem if the data has been stored for too long even when not powered on.

Therefore, it has been an issue that needs to be solved urgently in the industry to overcome the above-mentioned problems that cannot be solved by prior art technologies and at the same time improve the overall performance of a flash memory.

### SUMMARY OF THE INVENTION

In view of the above problems, one object of the present invention is to provide a method and a system for refreshing a flash memory device so that the operation of refreshing the flash memory device can be forced to be executed until all valid data blocks are refreshed by sending a refresh command from the host.

Another object of the present invention is to provide a method and a system for refreshing a flash memory device, so that the host directly sends a refresh command to force a refresh operation to be executed on the flash memory device to refresh all valid data blocks, when a performance value of the flash memory device is lower than a pre-determined value.

In order to achieve the foregoing objects, the present invention provides a method for refreshing a flash memory device. The flash memory device includes a main control unit and a plurality of flash memory units. The method includes the following steps: A performance value related to the plurality of flash memory units is sent from the main control unit to a host. A refresh command is sent from the host to the main control unit when the performance value is lower than a pre-determined value. The main control unit is enabled to stop current operations of the plurality of flash memory units and execute a refresh operation on the plurality of flash memory units.

In order to achieve the foregoing objects, the present invention further provides a method for refreshing a flash memory device. The flash memory device includes a main control unit and a plurality of flash memory units. The method includes the following steps: A refresh command is sent from a host to the main control unit. The main control unit is enabled to stop current operations of the plurality of flash memory units and execute a refresh operation on the plurality of flash memory units.

In order to achieve the foregoing objects, the present invention further provides a system for refreshing a flash memory device. The system includes a host, a main control unit, and a plurality of flash memory units. The main control unit is disposed in the flash memory device and connected to the host. The plurality of flash memory units are disposed in the flash memory device and connected to the main control unit. The host is configured to send a refresh command to the main control unit to enable the main control unit to stop current operations of the plurality of flash memory units and execute a refresh operation on the plurality of flash memory units.

In summary, the method and system for refreshing a flash memory device according to the present invention can execute the operation of refreshing the flash memory device to refresh all valid data blocks by sending a refresh command directly from the host. After the refresh command is executed, not only the efficiency of the flash memory device can be completely improved, but also the data retention capability can be enhanced.

For further descriptions and advantages of the present invention, please refer to the subsequent drawings and embodiments, so as to understand the technical solutions of the present invention more clearly.

### BRIEF DESCRIPTION OF THE DRAWINGS

The above embodiments and advantages of the present invention will become more readily apparent to those ordinarily skilled in the art after reviewing the following detailed descriptions and accompanying drawings.

FIG. 1 is a block diagram of a system for refreshing a flash memory device according to one embodiment of the present invention.

FIG. 2 is a flow chart of a method for refreshing a flash memory device according to one embodiment of the present invention.

### DETAILED DESCRIPTION OF THE PREFERRED EMBODIMENTS

Please refer to all figures of the present invention when reading the following detailed description, wherein all figures of the present invention demonstrate different embodiments of the present invention by showing examples, and help the skilled person in the art to understand how to implement the present invention. The present examples provide sufficient embodiments to demonstrate the spirit of the present invention, each embodiment does not conflict with the others, and new embodiments can be implemented through an arbitrary combination thereof, i.e., the present invention is not restricted to the embodiments disclosed in the present specification. Unless there are other restrictions defined in the specific example, the following definitions apply to the terms used throughout the specification.

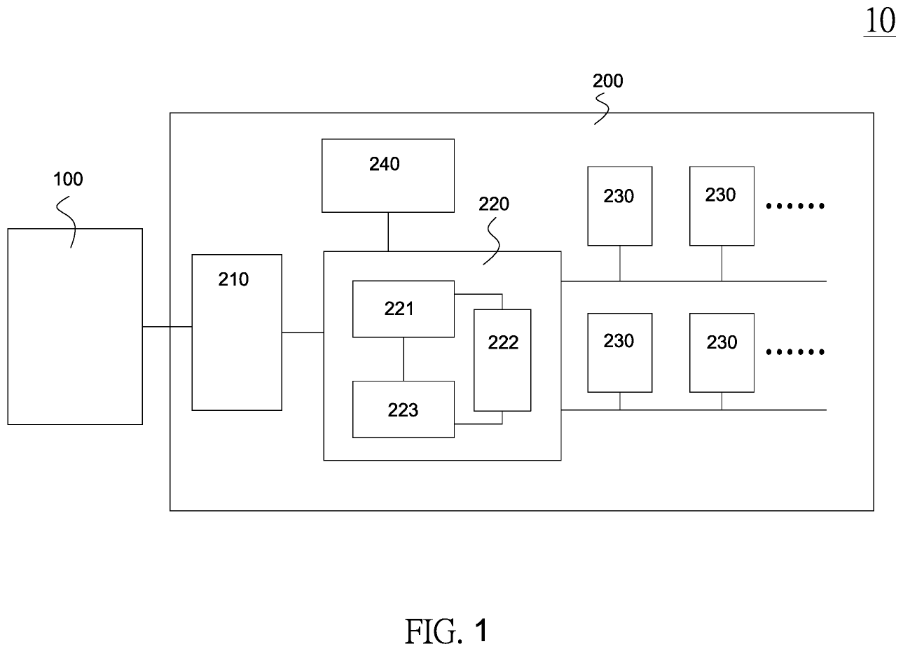

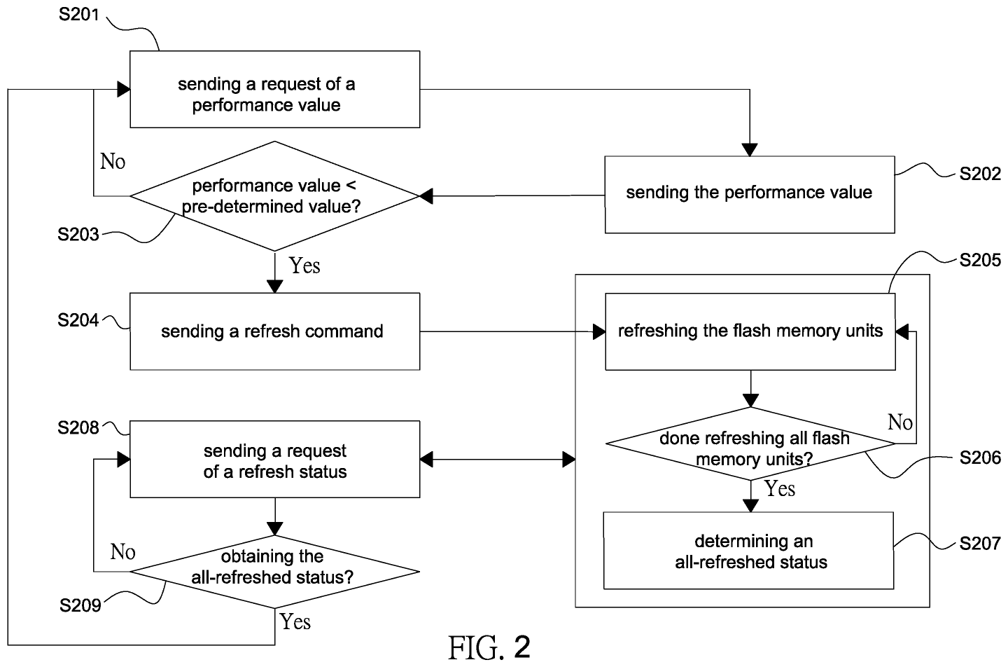

Please refer to FIG. 1 and FIG. 2, which are respectively a block diagram of a system for refreshing a flash memory device and a flow chart of a method for refreshing a flash memory device according to one embodiment of the present invention. In FIG. 1, the system 10 for refreshing a flash memory device 200 according to one embodiment of the present invention is applicable to the method for refreshing a flash memory device shown in FIG. 2.

In FIG. 1, the system 10 for refreshing a flash memory device 200 includes a host 100 and the flash memory device 200. In one embodiment, the host 100 is any device that can send a refresh command, for example, a personal computer or a device with a microcontroller (MCU) that has an operation system such as Windows or Linux. In one embodiment, the communication between the host 100 and the flash memory device 200 complies with the requirements of non-volatile memory express (NVMe), serial advanced technology attachment (SATA) or inter-integrated circuit (I²C) bus, or is triggered by a general-purpose input/output (GPIO).

In FIG. 1, the flash memory device 200 includes an interface unit 210, a main control unit 220 and a plurality of flash memory units 230. The interface unit 210 is configured to receive the refresh command from the host 100, and send the refresh command to the main control unit 220. The refresh command complies with the requirements of the non-volatile memory express (NVMe), the serial advanced technology attachment (SATA), the inter-integrated circuit (I²C) bus or the general-purpose input/output (GPIO). After receiving the refresh command, the main control unit 220 controls a plurality of flash memory units 230 to stop the current operations and perform a refresh operation on the plurality of flash memory units 230.

In one embodiment, the main control unit 220 includes a processing unit 221, a control logic unit 222 and a buffer management unit 223. The processing unit 221 is configured to communicate with the host 100 through the interface unit 210. The control logic unit 222 is connected between the processing unit 221 and the plurality of flash memory units 230, and is configured to control the refresh operation of the plurality of flash memory units 230 under the control of the processing unit 221. The buffer management unit 223 is connected between the control logic unit 222 and the processing unit 221, and is configured to temporarily store data originally stored in the plurality of flash memory units 230 during the refresh operation.

In one embodiment, the flash memory device 200 further includes a performance estimation unit 240, which is connected to the main control unit 220 and is configured to send a performance value to the main control unit 220 according to the performance of the plurality of flash memory units 230. When the main control unit 220 determines that the performance value is lower than a pre-determined value, the main control unit 220 controls the plurality of flash memory units 230 to stop current operations and performs a refresh operation on the plurality of flash memory units 230. In another embodiment, in response to the request by the host 100, the main control unit 220 can also send the performance value to the host 100. Then, a refresh command is sent from the host 100 to the main control unit 220. After receiving the refresh command, the main control unit 220 controls the plurality of flash memory units 230 to stop current operations and executes a refresh operation on the plurality of flash memory units 230.

In FIG. 2, the method for refreshing a flash memory device includes the following steps: First, in Step S201, the host 100 sends a request to the flash memory device 200 to obtain a performance value. In one embodiment, the request complies with the requirements of the non-volatile memory express (NVMe), the serial advanced technology attachment (SATA), the inter-integrated circuit (I²C) bus or the general-purpose input/output (GPIO).

After receiving the request to obtain the performance value, in Step S202, the main control unit 220 of the flash memory device 200 responds to the host 100 with a performance value of the plurality of flash memory units 230. In one embodiment, the performance value of the plurality of flash memory units 230 can be a value obtained by detecting the performance in any way. For example, in one embodiment, the performance value can be provided to the main control unit 220 by the performance estimation unit 240 based on the performance of the plurality of flash memory units 230.

Next, in Step S203, the host 100 determines whether the performance value is lower than a pre-determined value. In one embodiment, the host 100 can determine whether the performance value is lower than the pre-determined value through firmware, software or hardware implementations. If the performance value is lower than the pre-determined value, in Step S204, a refresh command is sent from the host 100 to the main control unit 220 of the flash memory device 200. In one embodiment, the refresh command complies with the requirements of the non-volatile memory express (NVMe), the serial advanced technology attachment (SATA), the inter-integrated circuit (I²C) bus or the general-purpose input/output (GPIO). If the performance value is not lower than the pre-determined value, the process returns to Step S201.

After the main control unit 220 of the flash memory device 200 receives the refresh command, in Step S205, the main control unit 220 controls the plurality of flash memory units 230 to stop current operations, and executes a refresh operation on the plurality of flash memory units 230. In one embodiment, during the refresh operation, the data stored in at least one of the plurality of flash memory units 230 is first copied to the buffer management unit 223, then the data stored in the at least one of the plurality of flash memory units 230 is erased, and finally the copied data is rewritten from the buffer management unit 223 to the at least one of the plurality of flash memory units 230.

In Step S206, the main control unit 220 determines whether the plurality of flash memory units 230 is completely refreshed. If the plurality of flash memory units 230 are completely refreshed, in Step S207, the main control unit 220 determines that the plurality of flash memory units 230 is in an all-refreshed status. If the plurality of flash memory units 230 are not all refreshed, the process returns to Step S205 and the refresh operation continues.

Regardless of whether Step S205 has been executed, Step S208 can be executed at any time, in which the host 100 sends a request to obtain a refresh status. Further, in Step S209, it is determined whether the host 100 has obtained the all-refreshed status. If the host 100 has not obtained the all-refreshed status, the process returns to Step S208; and if the host 100 has obtained the all-refreshed status, the process returns to Step S201.

However, in another embodiment, the method for refreshing a flash memory device can be started by the user directly performing Step S204. In other words, regardless of the performance of the plurality of flash memory units 230, the user can directly execute Step S204 through an interface (not shown) on the host 100 to provide a refresh command from the host 100 to the main control unit 220 of the flash memory device 200 to force the execution of Step S205, such that the main control unit 220 controls the plurality of flash memory units 230 to stop current operations and execute a refresh operation on the plurality of flash memory units 230. The advantage of this embodiment is that the user can decide the timing of starting refreshing the flash memory device 200 when the operating load of the plurality of flash memory units 230 is lighter, or even when they are idle, which not only enhances the efficiency of refreshing the flash memory device 200, but also improves the performance of the flash memory device 200 after the refresh operation.

As discussed above, it can be seen that the method and system for refreshing a flash memory device according to the present invention can refresh the flash memory device by directly sending a refresh command from the host to force an refresh operation of the flash memory device to refresh all valid data blocks. After completing the refresh operation, not only the efficiency of the flash memory device can be improved, but also the data retention capability can be enhanced.

While the invention has been described in terms of what is presently considered to be the most practical and preferred embodiments, it is to be understood that the invention need not be limited to the disclosed embodiments. On the contrary, it is intended to cover various modifications and similar arrangements included within the spirit and scope of the appended claims which are to be accorded with the broadest interpretation so as to encompass all such modifications and similar structures.

1. A method for refreshing a flash memory device, wherein the flash memory device comprises a main control unit and a plurality of flash memory units, the method comprising steps of:
sending a performance value related to the plurality of flash memory units from the main control unit to a host;
sending a refresh command from the host to the main control unit when the performance value is lower than a pre-determined value; and
enabling the main control unit to stop current operations of the plurality of flash memory units and execute a refresh operation on the plurality of flash memory units.

2. The method as claimed in claim 1, prior to the step of sending the performance value from the main control unit, the method further comprising a step of:
sending a request of the performance value related to the plurality of flash memory units from the host to the main control unit.

3. The method as claimed in claim 1, after the main control unit executes the refresh operation, the method further comprising a step of:
sending a refresh status from the main control unit to the host to show whether each of the plurality of flash memory units has been refreshed.

4. The method as claimed in claim 1, wherein the refresh command conforms to the requirements of non-volatile memory express (NVMe), serial advanced technology attachment (SATA), inter-integrated circuit (I²C) bus or general-purpose input/output (GPIO).

5. The method as claimed in claim 1, wherein:
the main control unit is electrically connected to the host; and
the plurality of flash memory units are electrically connected to the main control unit.

6. The method as claimed in claim 1, wherein the main control unit comprises:
a processing unit configured to electrically communicate with the host through an interface unit;
a control logic unit electrically connected between the processing unit and the plurality of flash memory units and configured to be controlled by the processing unit to control the refresh operation on the plurality of flash memory units; and
a buffer management unit electrically connected between the control logic unit and the processing unit and configured to temporarily store data originally stored in the plurality of flash memory units during the refresh operation.

7. A method for refreshing a flash memory device, wherein the flash memory device comprises a main control unit and a plurality of flash memory units, the method comprising steps of:
sending a refresh command from a host to the main control unit; and
enabling the main control unit to stop current operations of the plurality of flash memory units and execute a refresh operation on the plurality of flash memory units.

8. The method of claim 7, after the main control unit executes the refresh operation, the method further comprising a step of:
sending a refresh status from the main control unit to the host to show whether each of the plurality of flash memory units has been refreshed.

9. The method of claim 7, wherein the refresh command conforms to the requirements of non-volatile memory express (NVMe), serial advanced technology attachment (SATA), inter-integrated circuit (I²C) bus or general-purpose input/output (GPIO).

10. The method as claimed in claim 7, wherein:
the main control unit is connected to the host; and
the plurality of flash memory units are connected to the main control unit.

11. The method as claimed in claim 7, wherein the main control unit comprises:
a processing unit configured to communicate with the host through an interface unit;
a control logic unit connected between the processing unit and the plurality of flash memory units and configured to be controlled by the processing unit to control the refresh operation on the plurality of flash memory units; and
a buffer management unit connected between the control logic unit and the processing unit and configured to temporarily store data originally stored in the plurality of flash memory units during the refresh operation.

12. A system for refreshing a flash memory device, the system comprising:
a host;
a main control unit disposed in the flash memory device and connected to the host; and
a plurality of flash memory units disposed in the flash memory device and connected to the main control unit,
wherein the host is configured to send a refresh command to the main control unit to enable the main control unit to stop current operations of the plurality of flash memory units and execute a refresh operation on the plurality of flash memory units.

13. The system as claimed in claim 12, wherein the main control unit comprises:
a processing unit configured to communicate with the host through an interface unit;
a control logic unit connected between the processing unit and the plurality of flash memory units and configured to be controlled by the processing unit to control the refresh operation on the plurality of flash memory units; and
a buffer management unit connected between the control logic unit and the processing unit and configured to temporarily store data originally stored in the plurality of flash memory units during the refresh operation.

14. The system as claimed in claim 12, wherein the refresh command conforms to the requirements of non-volatile memory express (NVMe), serial advanced technology attachment (SATA), inter-integrated circuit (I²C) bus or general-purpose input/output (GPIO).
